(19) United States
(12) Patent Application Publication
(10) Pub. No.: US 2015/0091089 A1
(43) Pub. Date: Apr. 2, 2015

(54) AIR-SPACER MOS TRANSISTOR

(71) Applicants: STMICROELECTRONICS (CROLLES 2) SAS, Crolles (FR); STMICROELECTRONICS SA, Montrouge (FR); Commissariat A L'Energie Atomique et aux Energies Alternatives, Paris (FR)

(72) Inventors: Heimanu Niebojewski, Grenoble (FR); Yves Morand, Grenoble (FR); Cyrille Le Royer, Tullins (FR); Olivier Rozeau, Moirans (FR)

(73) Assignees: STMICROELECTRONICS (CROLLES 2) SAS, Crolles (FR); STMICROELECTRONICS SA, Montrouge (FR); Commissariat A L'Energie Atomique et aux Energies Alternatives, Paris (FR)

(21) Appl. No.: 14/499,545

(22) Filed: Sep. 29, 2014

(30) Foreign Application Priority Data
Sep. 30, 2013 (FR) 1359386

(51) Int. Cl. H01L 29/51; H01L 29/66; H01L 29/08; H01L 29/78

(52) U.S. Cl. CPC H01L 29/515; H01L 29/78; H01L 29/66575; H01L 29/6656; H01L 29/6653; H01L 29/0843
USPC 257/347; 438/151; 438/595

(57) ABSTRACT

A MOS transistor has a gate insulator layer that is made of a material of high dielectric constant deposited on a substrate. The gate insulator layer extends, with a constant thickness, under and beyond a gate stack. Spacers of low dielectric constant are formed on either side of the gate stack and vertically separated from the substrate by the extension of the gate insulator layer beyond the sides of the gate stack. The spacers of low dielectric constant are preferably air spacers.

### PRIORITY CLAIM

This application claims the priority benefit of French Patent application number 1359386, filed on Sep. 30, 2013, the contents of which is hereby incorporated by reference in its entirety to the maximum extent allowable by law.

### TECHNICAL FIELD

The present disclosure relates to MOS transistors, and more specifically to air-spacer MOS transistors.

### BACKGROUND

In the forming of a MOS transistor, it is generally desired to decrease the switching power consumption and to increase the switching speed. Such parameters especially depend on the gate-source contact and gate-drain contact capacitances.

Such stray capacitances tend to become particularly significant in the case of MOS transistors of very small size, where the gate lengths are shorter than some hundred nanometers and especially shorter than 20 nm. Indeed, in this case, the distances between the gate, on the one hand, the source contact and the drain contact, on the other hand, become extremely small. A solution to decrease such stray capacitances comprises surrounding the sides of the gate on either side of its length with air (vacuum) spacers instead of conventionally using spacers made of a solid dielectric material. This is for example described in article “Air Spacer MOSFET Technology for 20 nm Node and Beyond” by Jemin Park and Chenming Hu, 9th ICSICT—Oct. 20-23, 2008—IEEE 2008 (the disclosure of which is incorporated by reference).

FIG. 1 shows a MOS transistor formed on a semiconductor substrate 1 covered with a conductive gate stack 3 separated from the substrate by a gate insulator layer 4 made of a material of high dielectric constant. The source and drain 5 are arranged on either side of the gate in the substrate. The gate is surrounded with spacers 7 made of a dielectric material of low dielectric constant. The assembly of the conductive gate stack and of the spacers is surrounded with an insulator 8 having metal vias 9 forming the source and drain contacts formed therethrough.

The article “Impacts of High-K Offset Spacer in 65-nm Node SOI Devices” by Ma Ming-Wen et al.—Electron Device Letters—2007 and the article “Impact of high-k dielectrics and spacer layers on the electrical performance of symmetrical double gate MOSFETs” by Bhattacherjee S et Biswas A.—International Conference on Emerging Trends in Electronic and Photonic Devices and Systems—2009 (both of which are incorporated by reference) teach that the value of the dielectric constant of the spacer material has an influence on the static performance of the MOS transistor. In particular, the fact of decreasing the value of the dielectric constant of the spacer material results in a deterioration of this static performance by increase of the threshold voltage and by decrease of the value of the drain-source current for a given drain-source voltage and gate-source voltage couple.

It would be desirable to benefit both from the advantages of spacers made of a material of low dielectric constant to decrease stray capacitances, and from the advantages of spacers made of a material of high dielectric constant to improve the static performance of a MOS transistor.

### SUMMARY

Thus, an embodiment provides a MOS transistor having its gate insulator layer made of a material of high dielectric constant extending, at constant thickness, under and in contact with spacers of low dielectric constant.

According to an embodiment, the gate insulator layer made of a material of high dielectric constant extends under the entire base of the spacers of low dielectric constant.

According to an embodiment, the spacers of low dielectric constant are air spacers.

According to an embodiment, a protection layer is present between the air spacer and the assembly formed of the conductive gate stack and of the gate insulator.

According to an embodiment, the MOS transistor comprises epitaxial drain and source bosses.

According to an embodiment, the contacts with the source and the drain are self-aligned.

According to an embodiment, the MOS transistor is formed on top of and inside of a silicon-on-insulator substrate.

Another embodiment provides a MOS transistor manufacturing method comprising the steps of: a) depositing on a substrate a gate insulator layer of high dielectric constant; b) successively depositing materials which will form a conductive gate stack; c) delimiting the conductive gate stack by leaving in place the gate insulator; d) forming around the conductive gate stack first spacers of low dielectric constant; and e) etching the gate insulator by using the spacer and the conductive gate stack as a mask.

According to an embodiment, the method further comprises, between steps c) and d), a step of uniformly depositing a protection layer.

According to an embodiment, the method comprises, after step e), a step of forming bosses by epitaxy of a semi-conductor material on either side of the conductive gate stack on the exposed regions of the substrate.

According to an embodiment, the method further comprises the step of forming second spacers on either side of the first spacers.

According to an embodiment, the method further comprises the steps of: covering the entire structure with an insulating material along a height at least equal to the height of the conductive gate stack; planarizing the surface of said insulating material to expose the top of the spacers; removing by etching the spacers to form air spacers; closing the upper aperture of the air spacers; and forming in the insulating material covering the structure metal vias of contact with the source and drain regions.

According to an embodiment, the method further comprises the steps of: covering the entire structure with a metal or with a conductive metal alloy forming contacts self-aligned with the drain and source regions; planarizing the surface of the metal or of the metal alloy to expose the top of the spacers; removing by etching the spacers to form the air spacers; and closing the upper aperture of the air spacers.

### BRIEF DESCRIPTION OF THE DRAWINGS

The foregoing and other features and advantages will be discussed in detail in the following non-limiting description of specific embodiments in connection with the accompanying drawings, wherein:

FIG. 1 is a cross-section view showing a conventional MOS transistor;

FIG. 2 is a cross-section view showing an embodiment of a MOS transistor;

FIG. 3 is a cross-section view showing a first embodiment of an air-spacer MOS transistor;

FIG. 4 is a cross-section view showing a second embodiment of an air-spacer MOS transistor;

FIGS. 5 to 11 are cross-section views showing successive steps of the second embodiment of an air-spacer MOS transistor; and

FIG. 12 is a cross-section view showing a manufacturing step specific to the first embodiment of an air-spacer MOS transistor.

### DETAILED DESCRIPTION OF THE DRAWINGS

For clarity, the same elements have been designated with the same reference numerals in the various drawings and, further, as usual in the representation of integrated circuits, the various drawings are not to scale.

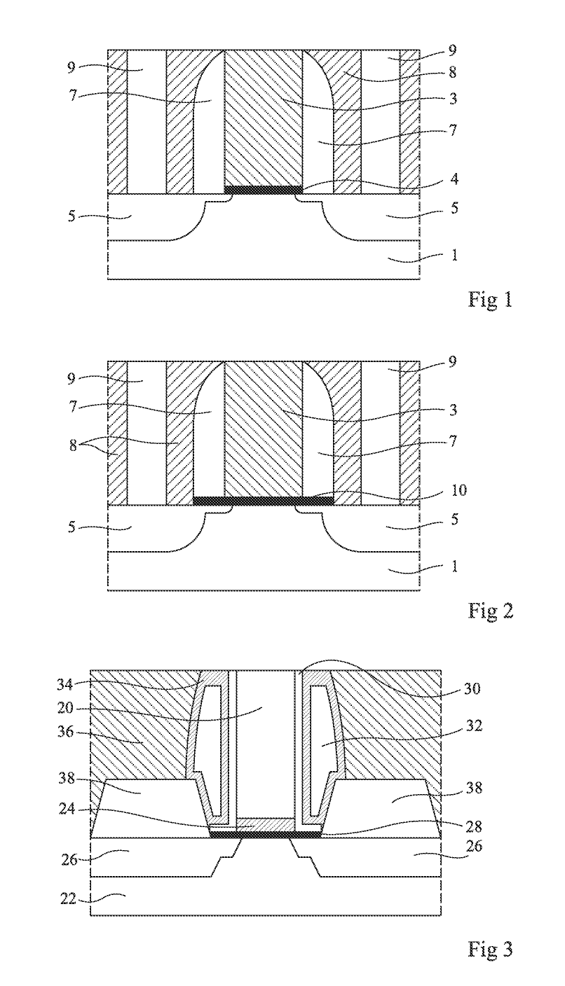

FIG. 2 schematically shows a MOS transistor structure where the same elements as in FIG. 1 are designated with the same reference numerals. Thus, FIG. 2 illustrates a substrate 1, a conductive gate stack 3, source and drain regions 5, spacers 7 of a material of low dielectric constant, and source and drain contact metal vias 9.

Conversely to the MOS transistor of FIG. 1, in the MOS transistor of FIG. 2, gate insulator layer 10 made of a material of high dielectric constant is present not only under conductive gate stack 3 but also, at constant thickness, under and in contact with spacers 7.

The presence of a material of high dielectric constant 10 extending beyond gate stack 3 and separating spacers 7 from substrate 1 gives the MOS transistor the static performance described as being associated with the use of spacers of a material of high dielectric constant while keeping low stray capacitances associated with the use of spacers made of a material of low dielectric constant.

U.S. Pat. No. 7,812,411 (incorporated herein by reference) describes a MOS transistor where a material of high dielectric constant is arranged under air spacers. The described solution and the method for obtaining it are highly complex.

FIG. 3 schematically shows a specific embodiment of an air-spacer MOS transistor of the type of in FIG. 2. A conductive gate stack 20, 24 is formed above a substrate 22. Conductive gate stack 20, 24 is essentially formed of doped polysilicon in its upper portion 20 and comprises in its lower portion, close to substrate 22, a layer made of conductive metal or of a metal alloy 24. On either side of conductive gate stack 20, 24, drain and source regions 26 are formed in substrate 22. Conductive gate stack 20, 24 is separated from substrate 22 by a gate insulator layer 28 of a material of high dielectric constant. Gate insulator layer 28 extends, at constant thickness, at the surface of substrate 22 beyond conductive gate stack 20, 24 on either side thereof.

A layer 30 of insulating material is arranged along gate stack 20, 24 and above the extension of gate insulator 28.

On either side of conductive gate stack 20 are formed air spacers 32 delimited by a layer of a dielectric material 34, for example, silicon nitride. Layer 34 is separated from substrate 22 by the two layers of material 30 and 28, extensions of layer 28 running under the entire base of air spacers 32.

Beyond air spacers 32 are regions of contact 36 with drain and source 26. In the embodiment illustrated in FIG. 3, regions 38 appear above drain and source regions 26. Regions 38 are semiconductor regions formed by epitaxy and intended to thicken drain and source regions 26.

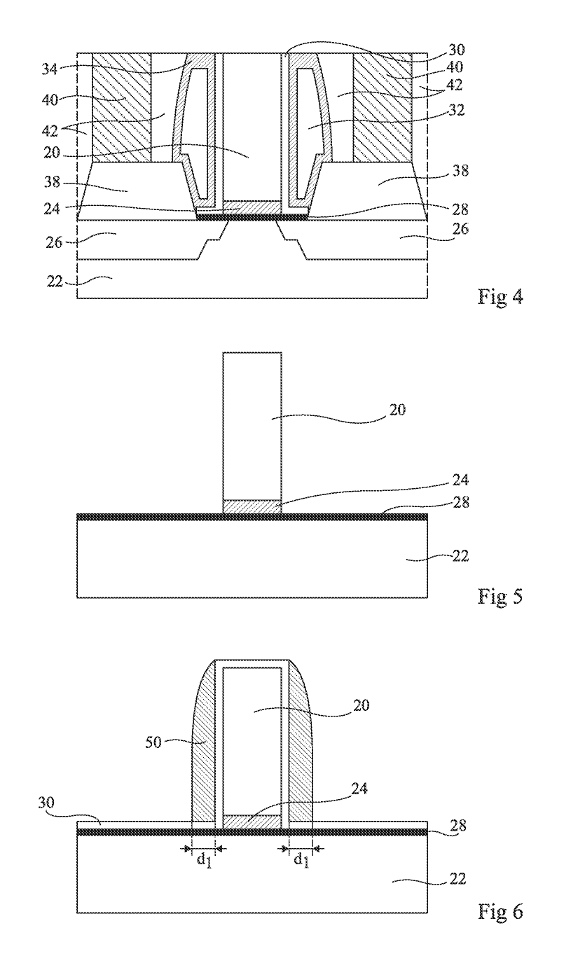

FIG. 4 schematically shows another embodiment of an air-spacer transistor. In this drawing, the same elements as in FIG. 3 are designated with the same reference numerals. The structure of the transistor of FIG. 4 comprises regions 40 of contact with the source and the drain. Contact regions 40 are formed of metal vias crossing an insulating material 42 surrounding the entire conductive gate stack 20, 24 and air spacers 32. Insulating material 42 extends beyond contact regions 40 above substrate 22.

FIGS. 5 to 11 schematically illustrate different steps of manufacturing the MOS transistor shown in FIG. 3.

At the step illustrated in FIG. 5, conductive gate stack 20, 24 has been formed on gate insulator layer 28. Gate insulator layer 28 made of a material of high dielectric constant is present over the entire surface of substrate 22. The described structure is obtained by depositing on substrate 22 a gate insulator layer 28 having materials forming conductive gate stack 20, 24 successively deposited thereon and then by delimiting conductive gate stack 20, 24 by etching. The etching of metal 24 should be selective over that of gate insulator layer 28.

The gate may have a length in the range from 10 to 30 nm. A 15-nm gate length is considered hereafter as an example. Layer 28 may be HfSiON of a thickness between 0.8 and 3 nm, typically 2 nm. The semiconductor substrate may be made of silicon, for example, solid silicon, or a thin silicon on insulator (SOI) layer. Conductive gate stack 20, 24 may be made in its upper portion 20 of polysilicon or of doped polycrystalline SiGe. This upper portion may have a height in the range from 10 to 50 nm, typically 30 nm. Metal layer 24 of the conductive gate stack may be made of titanium nitride (TiN) and have a thickness in the range from 2 to 10 nm, typically 5 nm.

At the step illustrated in FIG. 6, a protection insulator layer 30 has been conformally deposited over the entire structure. Layer 30 may be formed by chemical vapor deposition (CVD) or atomic layer deposition (ALD). Layer 30 may be made of boron nitride having a thickness in the range from 2 to 4 nm. Sacrificial spacers 50 have been formed on either side of conductive gate stack 20, 24. Sacrificial spacers 50 may be made of silicon nitride and have a dimension d1 at their base in the range from 3 to 9 nm. It should be noted that the etching of spacers 50 should be selective over that of layer 30.

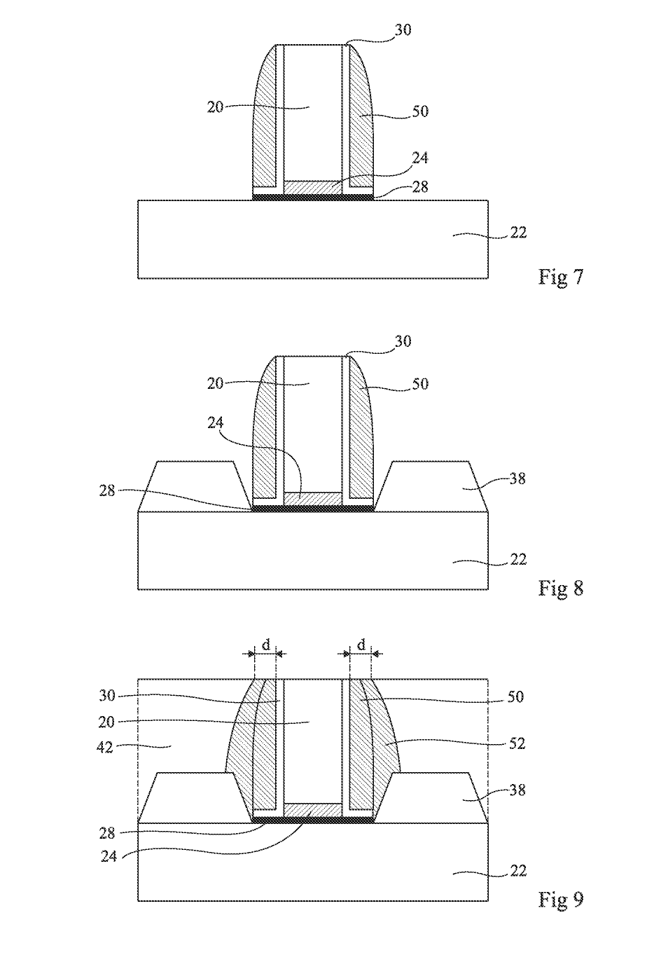

At the step illustrated in FIG. 7, a portion of gate insulator layer 28 and of protection layer 30 which used to extend beyond sacrificial spacers 50 in the structure shown in FIG. 6 have been suppressed by a dry etch method. The etching of gate insulator 28 should be selective over that of substrate 22. Thus, layer 28, topped with layer 30, only remains under conductive gate stack 20, 24 and under the entire length of sacrificial spacers 50.

FIG. 8 illustrates the result of a step of epitaxy of a semiconductor material on the exposed portions of substrate 22 to form bosses 38. This optional step is preferably, in particular, in the case where substrate 22 is a thin silicon-on-insulator layer (SOI).

At the step illustrated in FIG. 9, additional sacrificial spacers 52 have been formed on either side of sacrificial spacers 50. Additional sacrificial spacers 52, made of silicon nitride, for example, extend above a portion of regions 38. The entire structure is covered with an insulating material 42, silicon oxide, for example. A chemical-mechanical polishing step (CMP) is carried out to expose the upper portion of sacrificial spacers 50 and 52 along a length d.

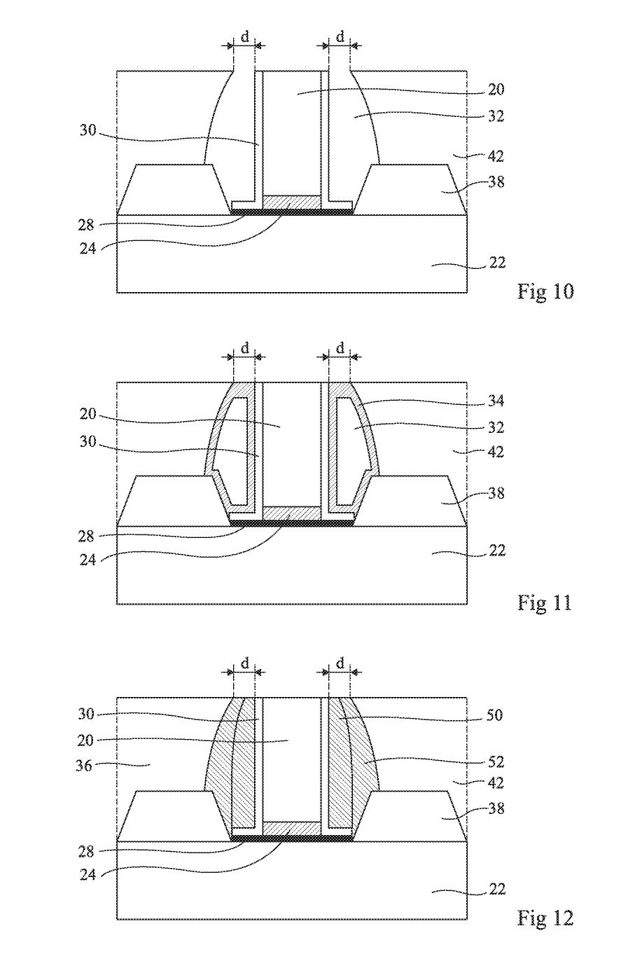

At the step illustrated in FIG. 10, sacrificial spacers 50 and 52 of FIG. 9 have been removed by selective etching. The etching should be selective over the materials of layer 30, of regions 38, and of insulator 42 as well as of material 20 of conductive gate stack 20, 24 (it may be provided for this last material to be covered with a masking layer, not shown). For silicon nitride spacers 50 and 52, the etching may be performed with orthophosphoric acid (H₃PO₄).

At the step illustrated in FIG. 11, the apertures of length d present at the tops of air spacers 32 have been sealed by the deposition of a dielectric material layer 34. Layer 34 is present at the surface of insulating material 42 and on the surfaces delimiting air spacers 32. The portion of layer 34 deposited above insulating material 42 has been removed, for example, by chemical-mechanical polishing (CMP).

Starting from the structure of FIG. 11, the transistor structure shown in FIG. 4 is conventionally obtained by conventionally forming metal contact vias 40 through insulating material 42, above regions 38.

FIGS. 5 to 9 and FIG. 12 schematically illustrate different steps of manufacturing the MOS transistor shown in FIG. 3.

At the step illustrated in FIG. 12, insulator 42 of the structure shown in FIG. 9 has been removed by selective etching. A metal deposition 36 has then been performed, for example, tungsten (W), titanium nitride (TiN), or titanium and tungsten nitride. The thickness of deposit 36 should be at least equal to the height of conductive gate stack 20, 24. The entire structure is then planarized by chemical-mechanical polishing (CMP) to expose the upper portion of sacrificial spacers 50 and 52 along a length d. Metal deposition 36 thus forms contacts self-aligned with regions 38.

The materials of sacrificial spacers 50 and 52 are then removed to form air spacers 32 (see, FIG. 10). A dielectric material layer 34, made of silicon nitride, for example, is then deposited on metal 36 and on the surfaces delimiting air spacers 32 (see, FIG. 11). Layer 34 seals the apertures of length d present at the tops of air spacers 32. The portion of layer 34 present above metal 36 is then removed by chem.-mech. polishing (CMP).

Specific embodiments have been described. Various alterations, modifications, and improvements will readily occur to those skilled in the art.

In particular, substrate 22 may correspond to a thin silicon-on-insulator (SOI) layer or may be a solid silicon substrate. Drain and source regions 26 may be formed by conventional implantation steps. A first implantation step will be carried out after forming gate stack 20, 24 in the structure shown in FIG. 5. A second implantation step will be carried out after forming sacrificial spacers 50.

The previously-described materials have been described as an example and it will be within the abilities of those skilled in the art to replace them with materials having same electric and mutual etch selectivity characteristics. Similarly, the previously mentioned dimensions have been indicated as an example and may be adapted to the technological processes used.

Although a manufacturing method where initial conductive gate stack 20, 24 is permanent, the conductive gate stack may be removed at the end of the process and replaced with another conductive gate stack.

Various protection or etch stop layers may be added or suppressed. In particular, the presence of protection layer 30 may be optional.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A MOS transistor, comprising a gate insulator layer made of a material of high dielectric constant which extends, with a constant thickness, under and in contact with air spacers delimited by a layer of a dielectric material present on sides of a conductive gate stack.

2. The MOS transistor of claim 1, wherein the gate insulator layer made of the material of high dielectric constant extends under an entire base of the spacers of low dielectric constant.

3. The MOS transistor of claim 1, wherein a protection layer is present between the air spacers and an assembly formed of the conductive gate stack and of the gate insulator layer.

4. The MOS transistor of claim 1, further comprising epitaxial drain and source bosses.

5. The MOS transistor of claim 1, further comprising self-aligned contacts with a source and a drain.

6. The MOS transistor of claim 1, further comprising a silicon-on-insulator substrate.

7. A method for manufacturing a MOS transistor, comprising:
depositing on a substrate a gate insulator layer of high dielectric constant;
successively depositing materials to form a gate conductor stack;
delimiting the conductive gate stack while leaving in place the gate insulator layer;
forming around the conductive gate stack first sacrificial spacers; and
etching the gate insulator by using the first sacrificial spacers and the conductive gate stack as a mask.

8. The method of claim 7, further comprising uniformly depositing a protection layer on the gate conductor stack and gate insulator layer.

9. The method of claim 7, further comprising forming bosses by epitaxy of a semiconductor material on either side of the conductive gate stack on regions of the substrate exposed by etching the gate insulator.

10. The method of claim 7, further comprising forming second spacers on either side of the first sacrificial spacers.

11. The method of claim 7, further comprising:
depositing an insulating material to a height at least equal to a height of the conductive gate stack;
planarizing a surface of the deposited insulating material to expose a top of the first sacrificial spacers;
etching away the first sacrificial spacers to form air spacers;
closing an upper aperture of the air spacers; and
forming in the deposited insulating material metal vias to make electrical contact with source and drain regions on either side of the gate conductor stack.

12. The method of claim 7, further comprising:
depositing a metal or a conductive metal alloy to form contacts self-aligned with drain and source regions on either side of the gate conductor stack;
planarizing a surface of deposited metal or conductive metal alloy to expose a top of the first sacrificial spacers;
etching away the first sacrificial spacers to form air spacers; and
closing the upper aperture of the air spacers.

13. A MOS transistor, comprising:
a substrate including a source region and a drain region with a substrate region between the source and drain regions;
a gate insulator layer extending on top of the substrate region and at least partially on top of the source and drain regions, the gate insulator layer made of a material of high dielectric constant and having a constant thickness;
a gate stack on top of the gate insulator layer above the substrate region;
a protection layer on sides of the gate stack and on top of the gate insulator layer; and
air spacers of low dielectric constant on either side of the gate stack and vertically separated from the substrate by the gate insulator layer and the protection layer and delimited by a layer of dielectric material present on sides of the gate stack.

14. The MOS transistor of claim 13, further comprising raised source and drain bosses extending above the source and drain regions in the substrate.

15. The MOS transistor of claim 13, wherein the substrate is a silicon on insulator (SOI) type substrate.

16. The MOS transistor of claim 14, further comprising:
raised source and drain bosses extending above the source and drain regions in the substrate; and
self-aligned contacts with the raised source and a drain bosses.

17. A method, comprising:
depositing a gate insulator layer of high dielectric constant on top of a substrate;
forming a gate stack on top of the gate insulator layer, the gate insulator layer extending laterally beyond side edges of the gate stack;
conformally depositing a protection layer on the gate insulator layer and side edges of the gate stack;
forming air spacers of low dielectric constant on either side of the gate stack, said spacers vertically separated from the substrate by the protection layer and the gate insulator layer and delimited by the protection layer.

18. The method of claim 17, wherein forming spacers comprises:
forming sacrificial material spacers on either side of the gate stack;
depositing covering material to cover the sacrificial material spacers and the gate stack;
exposing a top of the sacrificial material spacers; and
removing the sacrificial material spacers to form air spacers.
